(19) United States
(12) Patent Application Publication
(10) Pub. No.: US 2024/0419760 A1
(43) Pub. Date: Dec. 19, 2024

(54) MULTI-RULE DECISION METHOD FOR EVALUATING COMPREHENSIVE PERFORMANCE OF BATTERY STACK

(71) Applicant: CHINA UNIVERSITY OF PETROLEUM(EAST CHINA), Qingdao City (CN)

(72) Inventors: Yun LUO, Qingdao City (CN); Xuqian CHEN, Qingdao City (CN); Wenchun JIANG, Qingdao City (CN); Ming SONG, Qingdao City (CN); Yucai ZHANG, QingdaoCity (CN); Huibo MENG, Qingdao City (CN); Xiucheng ZHANG, Qingdao City (CN); Qinggui ZHANG, Qingdao City (CN); Guoyan ZHOU, Qingdao City (CN)

(21) Appl. No.: 18/497,038

(22) Filed: Oct. 30, 2023

(30) Foreign Application Priority Data
Jun. 16, 2023 (CN) 202310712784.X

(51) Int. Cl. G01R 31/367; G01R 31/385

(52) U.S. Cl. CPC G06F 17/18; G01R 31/367; G01R 31/385; G06F 17/11

(57) ABSTRACT

A multi-rule decision method of evaluating comprehensive performance of a battery stack includes selecting multiple indexes affecting the performance of the battery stack as a single-performance decision rule of the battery stack to form a decision rule vector. The method includes based on classical best worst method, obtaining a weight of each evaluation person of the comprehensive performance of the battery stack for the single-performance decision rule of the battery stack in the decision rule vector. The method includes based on entropy theory, aggregating the weight of the single-performance decision rule of the battery stack determined by each evaluation person of the comprehensive performance of the battery stack to obtain an importance weight of the evaluation persons of the comprehensive performance of the battery stack satisfying the iteration stop condition and a final comprehensive weight of the single-performance decision rule of the battery stack.

### TECHNICAL FIELD

The present disclosure relates to the field of battery stack technologies and in particular to a multi-rule decision method for evaluating comprehensive performance of a battery stack.

### BACKGROUND

Solid Oxide Fuel Cell (SOFC) battery stack, as a location for directly converting fuel chemical energy into electric energy, is a key core functional component in fuel cell generation system. In the entire SOFC generation system, the performance of the SOFC battery stack directly determines the reliability and durability of the generation system. But, there are many evaluation rules for determining the performance of the battery stack (including open circuit voltage, power, long-term cycle durability, and cold and hot cycle durability and the like, totaling more than 20 performance indexes). Furthermore, there is relevance between different evaluation rules as well as different importances. Moreover, different evaluation rules of the battery stack determines different performances of the battery stack. Therefore, it is of great significance for evaluation of the comprehensive performance of the battery stack to determine an importance weight of each evaluation rule of the battery stack by using a multi-rule decision method.

The multi-rule decision refers to performing aggregation and sorting on multiple solutions to be evaluated based on rule values of multiple rules. The multi-rule decision includes two parts: performing evaluation on the importance weights of the rules and performing sorting on the priorities of the solutions to be evaluated. The methods for performing evaluation on the importance of the rules include Analytic Hierarchy Process (AHP), Decision-Making Trial and Evaluation Laboratory (DEMATEL), Analytic Network Process (ANP), least square method, ordering relation analysis method, and period-on-period ratio analysis method and the like. In 2015, Rezaei proposed an all-new method of evaluating an importance weight of a rule: Best Worst Method (BWM). Compared with the existing multi-rule decision method, the BWM method can generate more consistent pairwise comparison so as to generate a more reliable result. But, this model is only applicable to a decision of evaluation personnel for comprehensive performance of a single battery stack.

Afterwards, Mohammadi and Rezaei also established Bayesian-BWM group decision model. But, this model is based on probability distribution to determine a weight of a decision rule of a single performance of a battery stack based on many hypothetical factors. In practical applications, there are still some defects. Most of other BWM group decision methods are to obtain an arithmetic mean of weights of a decision rule of a single performance of a battery stack determined by multiple evaluation persons of comprehensive performance of the battery stack, so as to determine a final weight of the decision rule of the single performance of the battery stack. But, this method neglects the influence of a personal preference of each evaluation person of the comprehensive performance of the battery stack on the decision result, leading to a lower reliability of the decision result.

The present disclosure provides a multi-rule decision method for evaluating comprehensive performance of a battery stack. This method is based on the classical BWM method to determine a weight of a single-performance decision rule of the battery stack determined by each evaluation person of the comprehensive performance of the battery stack, and based on entropy theory and computer, perform iteration on an importance weight of the evaluation persons of the comprehensive performance of the battery stack, and aggregate a preference of each evaluation person of the comprehensive performance of the battery stack so as to obtain a final comprehensive weight of the decision rule of the single performance of the battery stack.

### SUMMARY

The object of the present disclosure is to provide a multi-rule decision method of evaluating comprehensive performance of a battery stack, which effectively solves the problem in which the classical BWM method cannot allow multiple evaluation persons of the comprehensive performance of the battery stack to participate in decision and other BWM group decision models do not consider the contribution of each evaluation person of the comprehensive performance of the battery stack for a decision result.

In order to solve the above technical problems, the present disclosure adopts the following technical solution.

There is provided a multi-rule decision method of evaluating comprehensive performance of a battery stack, which is applied to evaluation of performance of an SOFC battery back and includes the following steps:
at step S1, selecting multiple indexes from indexes affecting the performance of the battery stack, including but not limited to airtightness, open-circuit voltage, power, long-term cycle durability, cold and hot cycle durability, generation efficiency, fuel utilization rate, startup time, internal reforming efficiency, and stable running current, as a single-performance decision rule of the battery stack for evaluating the comprehensive performance of the battery stack to form a decision rule vector Cⱼ=[c₁, c₂, . . . , cₙ] of the comprehensive performance of the battery stack;
at step S2, based on classical BWM method, obtaining a weight W^{k}ⱼ of each evaluation person of the comprehensive performance of the battery stack for the single-performance decision rule of the battery stack in the decision rule vector Cⱼ=[c₁, c₂, . . . , cₙ] of the comprehensive performance of the battery stack, wherein j=1, 2, 3, . . . , n, k=1, 2, 3, . . . , m, j represents the j-th single-performance decision rule of the battery stack, and k represents the k-th evaluation person of the comprehensive performance of the battery stack;
at step S3, based on entropy theory, aggregating a weight of the single-performance decision rule of the battery stack obtained by each evaluation person of the comprehensive performance of the battery stack to obtain an importance weight Uₖ of the k-th evaluation person of the comprehensive performance of the battery stack satisfying iteration stop condition and a final comprehensive weight Wⱼ of the j-th single-performance decision rule of the battery stack, determine a comprehensive performance level of the battery stack and further determine reliability and durability of a fuel cell generation system.

Furthermore, in the step S2, a method of obtaining the weight W^{k}ⱼ of the k-th evaluation person of the comprehensive performance of the battery stack for the j-th single-performance decision rule of the battery stack includes:
(1) selecting the most important single-performance decision rule c_{B} of the battery stack and the least important single-performance decision rule c_{W} of the battery stack from the decision rule vector Cⱼ=[c₁, c₂, . . . , cₙ] of the comprehensive performance of the battery stack;
(2) inviting each evaluation person of the comprehensive performance of the battery stack to use an importance value representation method of pairwise comparison to determine an importance of the most important single-performance decision rule of the battery stack relative to other single-performance decision rules of the battery stack and an importance of the other single-performance decision rules of the battery stack relative to the least important single-performance decision rule of the battery stack, and respectively establish a vector a_{Bj}=[a_{B1}, a_{B2}, . . . , a_{Bj-1}] of the importance of the most important single-performance decision rule of the battery stack relative to other single-performance decision rules of the battery stack and a vector a_{jW}=[a_{1W}, a_{2W}, . . . , a_{j-1W}] of the importance of the other single-performance decision rules of the battery stack relative to the least important single-performance decision rule of the battery stack;
(3) based on the following linear optimization formula, obtaining the weight W^{k}ⱼ of the single-performance decision rule of the battery stack determined by each evaluation person of the comprehensive performance of the battery stack;
under the precondition that a target function ξ^{L} is minimum, the following constraint conditions are to be satisfied:

$$\vert {w}_{B}^{k} - {a}_{Bj} {w}_{j}^{k} \vert \leq {ξ}^{L} ; \\ \vert {w}_{j}^{k} - {a}_{jw} {w}_{W}^{k} \vert \leq {ξ}^{L} ; \\ {\sum }_{j = 1}^{n} {w}_{j}^{k} = 1 ; \\ {w}_{j}^{k} \geq 0 ;$$

when j=1,2,3, . . . , n, the above constraint conditions are all to be established;
wherein w^{k}_{B} is a weight of the most important single-performance decision rule of the battery stack determined by the k-th evaluation person of the comprehensive performance of the battery stack;
w^{k}_{W} is a weight of the least important single-performance decision rule of the battery stack determined by the k-th evaluation person of the comprehensive performance of the battery stack;
w^{k}ⱼ is a weight vector formed by the weight of the j-th single-performance decision rule of the battery stack determined by the k-th evaluation person of the comprehensive performance of the battery stack;
ξ^{L} is the target function of the linear optimization formula.

Furthermore, in the step S3, a method of obtaining the importance weight Uₖ of the k-th evaluation person of the comprehensive performance of the battery stack and the final comprehensive weight W of the j-th single-performance decision rule of the battery stack includes:
(i) based on an optimal model aggregated relative to an entropy value in the group decision, aggregating a personal preference of each evaluation person of the comprehensive performance of the battery stack:

$${W}_{j}^{d} = \frac{{\prod }_{k = 1}^{m} {( {W}_{j}^{k} )}^{{U}_{k}^{d - 1}}}{{\sum }_{j = 1}^{n} {\prod }_{k = 1}^{m} {( {W}_{j}^{k} )}^{{U}_{k}^{d - 1}}}$$

wherein W^{k}ⱼ is a weight of the k-th evaluation person of the comprehensive performance of the battery stack for the j-th single-performance decision rule of the battery stack, Wⱼ^{d} is a comprehensive weight of the j-th single-performance decision rule of the battery stack calculated in the d-th iteration, Uₖ^{d-1} is an importance weight of the k-th evaluation person of the comprehensive performance of the battery stack calculated in the (d−1)-th iteration, wherein j=1, 2, 3, . . . , n, k=1, 2, 3, . . . , m, d is a number of iterations, d=1,2,3, . . . , h, h is determined by a specific number of iterations;
(ii) establishing a formula Uₖ^{d}=αrₖ^{d-1}+βeₖ^{d-1} of the importance weight of the k-th evaluation person of the comprehensive performance of the battery stack calculated in the d-th iteration;

wherein,

$${r}_{k}^{d - 1} = \frac{1}{{\sum }_{j = 1}^{n} {( {W}_{j}^{d - 1} - {W}_{j}^{k} )}^{2} {\sum }_{k = 1}^{m} \frac{1}{{\sum }_{j = 1}^{n} {( {W}_{j}^{d - 1} - {W}_{j}^{k} )}^{2}}} \\ {e}_{k}^{d - 1} = \frac{1 + \frac{1}{{log}_{2} n} ( {\sum }_{j = 1}^{n} ( \frac{{W}_{j}^{d - 1}}{{\sum }_{j = 1}^{n} {W}_{j}^{k}} {log}_{2} ( \frac{{W}_{j}^{d - 1}}{{\sum }_{j = 1}^{n} {W}_{j}^{k}} ) ) )}{m + {\sum }_{k = 1}^{m} ( \frac{1}{{log}_{2} n} {\sum }_{j = 1}^{n} ( \frac{{W}_{j}^{d - 1}}{{\sum }_{j = 1}^{n} {W}_{j}^{k}} {log}_{2} ( \frac{{W}_{j}^{d - 1}}{{\sum }_{j = 1}^{n} {W}_{j}^{k}} ) ) )}$$

wherein rₖ^{d-1} is a deviation weight obtained based on a total deviation amount of the comprehensive weight of the k-th evaluation person of the comprehensive performance of the battery stack calculated in the (d−1)-th iteration, eₖ^{d-1} is an entropy weight of the k-th evaluation person of the comprehensive performance of the battery stack in the (d−1)-th iteration, Uₖ^{d} is an importance weight of the k-th evaluation person of the comprehensive performance of the battery stack in the d-th iteration, W^{k}ⱼ is a weight of the k-th evaluation person of the comprehensive performance of the battery stack for the j-th single-performance decision rule of the battery stack, Wⱼ^{d-1} is a comprehensive weight of the j-th single-performance decision rule of the battery stack calculated in the (d−1)-th iteration, wherein [symbol] j=1,2,3, . . . , n, k=1,2,3, . . . , m, d is a number of iterations, d≥1, d=1,2,3, . . . , h, h is determined by a specific number of iterations, α and β are specified by the evaluation persons of the comprehensive performance of the battery stack based on actual situations, and α+β=1;
(iii) based on aggregation algorithm of personal preferences of multiple evaluation persons of the comprehensive performance of the battery stack, performing iteration, by computer, on the formulas (i) and (ii), until

$$\sqrt{{\sum }_{j = 1}^{n} {( ( {W}_{j}^{d - 1} ) - ( {W}_{j}^{d} ) )}^{2}} < ε ,$$

and stopping the iteration;

wherein ε is determined by the evaluation persons of the comprehensive performance of the battery stack based on actual situations, Wⱼ^{d} is a comprehensive weight of the j-th single-performance decision rule of the battery stack calculated in the d-th iteration, and Wⱼ^{d-1} is a comprehensive weight of the j-th single-performance decision rule of the battery stack calculated in the (d−1)-th iteration;
(iiii) outputting the importance weight Uₖ of the k-th evaluation person of the comprehensive performance of the battery stack at the time of iteration stop and the final comprehensive weight Wⱼ of the j-th single-performance decision rule of the battery stack, wherein Wⱼ=Wⱼ^{d}, Uₖ=Uₖ^{d}.

Furthermore, a flow of the aggregation algorithm of the personal preferences of multiple evaluation persons of the comprehensive performance of the battery stack includes:
P1: inputting the weight W^{k}ⱼ of the single-performance decision rule of the battery stack determined by each evaluation person of the comprehensive performance of the battery stack and an initial importance weight Uₖ⁰ of each evaluation person of the comprehensive performance of the battery stack;
P2: calculating a comprehensive weight value

$${W}_{j}^{1} = \frac{{\prod }_{k = 1}^{m} {( {W}_{j}^{k} )}^{{U}_{k}^{0}}}{{\sum }_{j = 1}^{n} {\prod }_{k = 1}^{m} {( {W}_{j}^{k} )}^{{U}_{k}^{0}}}$$

of the single-performance decision rule of the battery stack obtained in the first iteration;
P3: calculating an importance weight of each evaluation person of the comprehensive performance of the battery stack obtained in the first iteration;
P4: based on the comprehensive weight value Wⱼ¹ of the single-performance decision rule of the battery stack and the importance weight Uₖ¹ of each evaluation person of the comprehensive performance of the battery stack obtained in the first iteration, calculating a comprehensive weight value Wⱼ² of the j-th single-performance decision rule of the battery stack in the second iteration and the importance weight Uₖ² of the k-th evaluation person of the comprehensive performance of the battery stack in the second iteration;
P5: determining whether the iteration stop condition

$$\sqrt{{\sum }_{j = 1}^{n} {( ( {W}_{j}^{d - 1} ) - ( {W}_{j}^{d} ) )}^{2}} < ε ( d \geq 1 )$$

is satisfied; if the iteration stop condition is satisfied, stopping iteration and outputting Wⱼ^{d}, i.e. the final comprehensive weight Wⱼ of the j-th single-performance decision rule of the battery stack, and otherwise, repeating the iteration until the iteration stop condition is satisfied.

The present disclosure has the following beneficial effects:

The present disclosure is based on the classical BWM method to determine a weight of a single-performance decision rule of the battery stack determined by each evaluation person of the comprehensive performance of the battery stack, and based on entropy theory and computer, perform iteration on an importance weight of the evaluation persons of the comprehensive performance of the battery stack, and aggregate a preference of each evaluation person of the comprehensive performance of the battery stack so as to obtain a final comprehensive weight of the decision rule of the single performance of the battery stack. This method effectively solves the problem in which the classical BWM method cannot allow multiple evaluation persons of the comprehensive performance of the battery stack to participate in decision and other BWM group decision models do not consider the contribution of each evaluation person of the comprehensive performance of the battery stack for a decision result.

### BRIEF DESCRIPTIONS OF THE DRAWINGS

The present disclosure will be further detailed below in combination with drawings and specific embodiments.

FIG. 1 is a technical flowchart of an aggregation algorithm of personal preferences of multiple evaluation persons of the comprehensive performance of a battery stack according to the present disclosure.

### DETAILED DESCRIPTIONS OF EMBODIMENTS

There is provided a multi-rule decision method of evaluating comprehensive performance of a battery stack, which is applied to evaluation on performance of an SOFC battery stack and includes the following steps:
at step S1, selecting multiple indexes from performance indexes affecting the performance of the battery stack, comprising but not limited to airtightness, open-circuit voltage, power, long-term cycle durability, cold and hot cycle durability, generation efficiency, fuel utilization rate, startup time, internal reforming efficiency, and stable running current, as a single-performance decision rule of the battery stack for evaluating the comprehensive performance of the battery stack to form a decision rule vector Cⱼ=[c₁, c₂, . . . , cₙ] of the comprehensive performance of the battery stack;
at step S2, based on classical BWM method, obtaining a weight W^{k}ⱼ of each evaluation person of the comprehensive performance of the battery stack for the single-performance decision rule of the battery stack in the decision rule vector Cⱼ=[c₁, c₂, . . . , cₙ] of the comprehensive performance of the battery stack, wherein j=1,2,3, . . . , n, k=1, 2, 3, . . . , m, j represents the j-th single-performance decision rule of the battery stack, and k represents the k-th evaluation person of the comprehensive performance of the battery stack;
at step S3, based on entropy theory, aggregating a weight of the single-performance decision rule of the battery stack obtained by each evaluation person of the comprehensive performance of the battery stack to obtain an importance weight Uₖ of the k-th evaluation person of the comprehensive performance of the battery stack satisfying iteration stop condition and a final comprehensive weight Wⱼ of the j-th single-performance decision rule of the battery stack, determine a comprehensive performance level of the battery stack and further determine reliability and durability of a fuel cell generation system.

In the step S2, a method of obtaining the weight W^{k}ⱼ (j=1,2,3, . . . , n, k=1,2,3, . . . , m) of the k-th evaluation person of the comprehensive performance of the battery stack for the j-th single-performance decision rule of the battery stack includes:
(1) selecting the most important single-performance decision rule c_{B} of the battery stack and the least important single-performance decision rule c_{W} of the battery stack from the decision rule vector Cⱼ=[c₁, c₂, . . . , cₙ] of the comprehensive performance of the battery stack;
(2) inviting each evaluation person of the comprehensive performance of the battery stack to use an importance value representation method of pairwise comparison as shown in FIG. 2 to determine an importance of the most important single-performance decision rule of the battery stack relative to other single-performance decision rules of the battery stack and an importance of the other single-performance decision rules of the battery stack relative to the least important single-performance decision rule of the battery stack, and respectively establish a vector a_{Bj}=[a_{B1}, a_{B2}, . . . , a_{Bj-1}] of the importance of the most important single-performance decision rule of the battery stack relative to other single-performance decision rules of the battery stack and a vector a_{jW}=[a_{1W}, a_{2W}, . . . , a_{j-1W}] of the importance of the other single-performance decision rules of the battery stack relative to the least important single-performance decision rule of the battery stack;
(3) based on the following linear optimization formula, obtaining the weight W^{k}ⱼ of the single-performance decision rule of the battery stack determined by each evaluation person of the comprehensive performance of the battery stack;
under the precondition that a target function ξ^{L} is minimum, the following constraint conditions are to be satisfied:

$$\vert {w}_{B}^{k} - {a}_{Bj} {w}_{j}^{k} \vert \leq {ξ}^{L} ; \\ \vert {w}_{j}^{k} - {a}_{jw} {w}_{W}^{k} \vert \leq {ξ}^{L} ; \\ {\sum }_{j = 1}^{n} {w}_{j}^{k} = 1 ; \\ {w}_{j}^{k} \geq 0 ;$$

when j=1,2,3, . . . , n, the above constraint conditions are all to be established;
wherein w^{k}_{B} is a weight of the most important single-performance decision rule of the battery stack determined by the k-th evaluation person of the comprehensive performance of the battery stack;
w^{k}_{W} is a weight of the least important single-performance decision rule of the battery stack determined by the k-th evaluation person of the comprehensive performance of the battery stack;
w^{k}ⱼ is a weight vector formed by the weight of the j-th single-performance decision rule of the battery stack determined by the k-th evaluation person of the comprehensive performance of the battery stack;
ξ^{L} is the target function of the linear optimization formula;
wherein j=1,2,3, . . . , n, k=1,2,3, . . . , m.

In the step S3, a method of obtaining the importance weight Uₖ (k=1,2,3, . . . , m) of the k-th evaluation person of the comprehensive performance of the battery stack and the final comprehensive weight Wⱼ (j=1,2,3, . . . , n) of the j-th single-performance decision rule of the battery stack includes:
(i) based on an optimal model aggregated relative to an entropy value in the group decision, aggregating a personal preference of each evaluation person of the comprehensive performance of the battery stack:

$${{W}_{j}}^{d} = \frac{{\prod }_{k = 1}^{m} ( {( {{W}^{k}}_{j} )}^{{{U}_{k}}^{d - 1}}}{{\sum }_{j = 1}^{n} {\prod }_{k = 1}^{m} {( {{W}^{k}}_{j} )}^{{{U}_{k}}^{d - 1}}}$$

wherein W^{k}ⱼ is a weight of the k-th evaluation person of the comprehensive performance of the battery stack for the j-th single-performance decision rule of the battery stack, Wⱼ^{d} is a comprehensive weight of the j-th single-performance decision rule of the battery stack calculated in the d-th iteration, Uₖ^{d-1} is an importance weight of the k-th evaluation person of the comprehensive performance of the battery stack calculated in the (d−1)-th iteration, wherein j=1, 2, 3, . . . , n, k=1,2,3, . . . , m, d is a number of iterations, d=1,2,3, . . . , h, h is determined by a specific number of iterations;
(ii) establishing a formula Uₖ^{d}=αrₖ^{d-1}+βeₖ^{d-1} (k=1,2,3, . . . , m, d=0, 1, 2, 3, . . . , h) of the importance weight of the k-th evaluation person of the comprehensive performance of the battery stack calculated in the d-th iteration;

wherein,

$${{r}_{k}}^{d - 1} = \frac{1}{{\sum }_{j = 1}^{n} {( {{W}_{j}}^{d - 1} - {{W}^{k}}_{j} )}^{2} {\sum }_{k = 1}^{m} \frac{1}{{\sum }_{j = 1}^{n} {( {{W}_{j}}^{d - 1} - {{W}^{k}}_{j} )}^{2}}}$$

$${{e}_{k}}^{d - 1} = \frac{1 + \frac{1}{{log}_{2} n} ( {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}{m + {\sum }_{k = 1}^{m} ( \frac{1}{{log}_{2} n} {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}$$

wherein rₖ^{d-1} is a deviation weight obtained based on a total deviation amount of the comprehensive weight of the k-th evaluation person of the comprehensive performance of the battery stack calculated in the (d−1)-th iteration, eₖ^{d-1} is an entropy weight of the k-th evaluation person of the comprehensive performance of the battery stack in the (d−1)-th iteration, Uₖ^{d} is an importance weight of the k-th evaluation person of the comprehensive performance of the battery stack in the d-th iteration, W^{k}ⱼ is a weight of the k-th evaluation person of the comprehensive performance of the battery stack for the j-th single-performance decision rule of the battery stack, Wⱼ^{d-1} is a comprehensive weight of the j-th single-performance decision rule of the battery stack calculated in the (d−1)-th iteration, wherein [symbol] j=1, 2, 3, . . . , n, k=1,2,3, . . . , m, d is a number of iterations, d≥1, d=1,2,3, . . . , h, h is determined by a specific number of iterations, α and β are specified by the evaluation persons of the comprehensive performance of the battery stack based on actual situations, and α+β=1;
(iii) based on aggregation algorithm of personal preferences of multiple evaluation persons of the comprehensive performance of the battery stack, performing iteration, by computer, on the formulas (i) and (ii), until

$$\sqrt{{\sum }_{j = 1}^{n} {( ( {{W}_{j}}^{d - 1} ) - ( {{W}_{j}}^{d} ) )}^{2}} < ε$$

(if the iteration stop condition is satisfied when proceeding to the h-th iteration, ε is determined by the evaluation persons of the comprehensive performance of the battery stack based on actual situations) and stopping the iteration;

wherein Wⱼ^{d} is a comprehensive weight of the j-th single performance decision rule of the battery stack calculated in the d-th iteration, and Wⱼ^{d-1} is a comprehensive weight of the j-th single-performance decision rule of the battery stack calculated in the (d−1)-th iteration;
(iii) outputting the importance weight Uₖ (k=1,2,3, . . . , m) of the k-th evaluation person of the comprehensive performance of the battery stack at the time of iteration stop and the final comprehensive weight Wⱼ (j=1, 2, 3, . . . , n) of the j-th single-performance decision rule of the battery stack, wherein Wⱼ=Wⱼ^{d} (j=1,2,3, . . . , n), Uₖ=Uₖ^{d} (k=1,2,3, . . . , m).

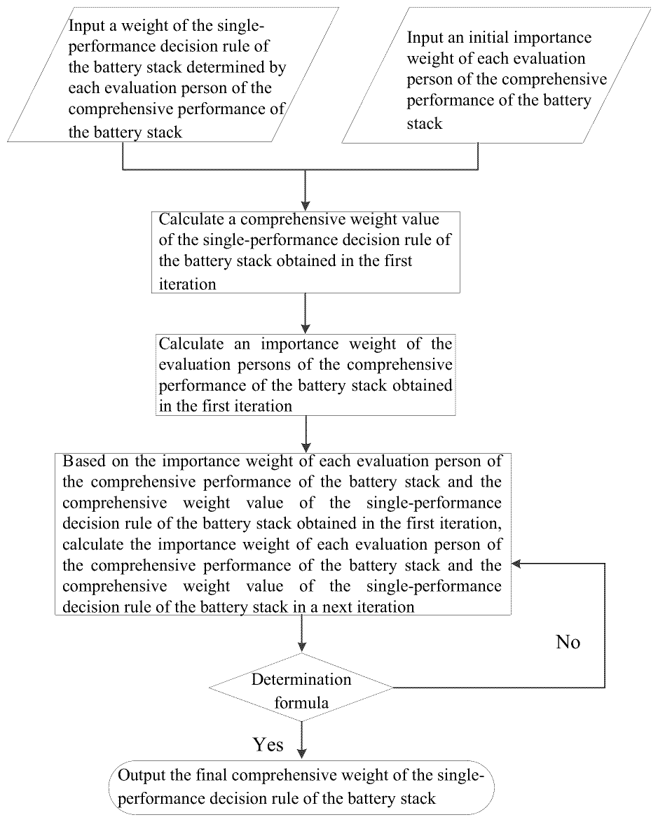

As shown in FIG. 1, a flow of the aggregation algorithm of the personal preferences of multiple evaluation persons of the comprehensive performance of the battery stack is further explained as follows:
P1: inputting the weight W^{k}ⱼ (j=1,2,3, . . . , n, k=1, 2, 3, . . . , m) of the single-performance decision rule of the battery stack determined by each evaluation person of the comprehensive performance of the battery stack and an initial importance weight Uₖ⁰ (k=1,2,3, . . . , m) of each evaluation person of the comprehensive performance of the battery stack;
P2: calculating a comprehensive weight value

$${{W}_{j}}^{1} = \frac{{\prod }_{k = 1}^{m} {( {{W}^{k}}_{j} )}^{{{U}_{k}}^{0}}}{{\sum }_{j = 1}^{n} {\prod }_{k = 1}^{m} {( {{W}^{k}}_{j} )}^{{{U}_{k}}^{0}}}$$

of the single-performance decision rule of the battery stack obtained in the first iteration;
P3: calculating an importance weight of each evaluation person of the comprehensive performance of the battery stack obtained in the first iteration;
P4: based on the comprehensive weight Uₖ^{d-1} of each evaluation person of the comprehensive performance of the battery tack in a last iteration and the comprehensive weight value Wⱼ^{d-1} of the single-performance decision rule of the battery stack, calculating the importance weight Uₖ^{d} of each evaluation person of the comprehensive performance of the battery tack in a next iteration and the comprehensive weight value Wⱼ^{d} of the single-performance decision rule of the battery stack, where d≥2;
P5: determining whether a determination formula is satisfied; if not, repeating the step P4 to perform iterative calculation; if yes, stopping the iteration and outputting the final comprehensive weight Wⱼ=Wⱼ^{d} of the single-performance decision rule of the battery stack, where the determination formula is below:

$$\sqrt{{\sum }_{j = 1}^{n} {( ( {{W}_{j}}^{d - 1} ) - ( {{W}_{j}}^{d} ) )}^{2}} < ε$$

### Embodiment 1

8 single-performance indexes are selected as the single-performance decision rule of the battery stack for determining the comprehensive performance of the battery stack: airtightness, open-circuit voltage, power, long-term cycle durability, cold and hot cycle durability, generation efficiency, fuel utilization rate and startup time.

1. Based on the classical BWM method, the weight W^{k}ⱼ (j=1, 2, 3, . . . , 8, k=1, 2, 3, 4, 5) of the single-performance decision rule of the battery stack obtained by five evaluation persons of the comprehensive performance of the battery stack by performing pairwise comparison on the single-performance decision rule of the battery stack is obtained, where j represents the j-th single-performance decision rule of the battery stack, and k represents the k-th evaluation person of the comprehensive performance of the battery stack.

(1) The most important single-performance decision rule c_{B} of the battery stack and the least important single-performance decision rule c_{W} of the battery stack are selected from the decision rule vector Cⱼ=[c₁, c₂, . . . , cₙ] of the comprehensive performance of the battery stack; five evaluation persons of the comprehensive performance of the battery stack select the most important single-performance decision rule of the battery stack and the least important single-performance decision rule of the battery stack from the eight single-performance decision rules of the battery stack, as shown in Table 1.

TABLE 1
The most important single-performance decision
rule of the battery stack and the least important single-
performance decision rule of the battery stack determined
by each evaluation person of the comprehensive
performance of the battery stack

| | The most important | The least important |
|---|---|---|
| | single-performance | single-performance |
| | decision rule | decision rule of the battery |
| | of the battery stack | stack |
| Evaluation person 1 | Power | Startup time |
| Evaluation person 2 | Power | Startup time |
| Evaluation person 3 | Open-circuit voltage | Startup time |
| Evaluation person 4 | Airtightness | Startup time |
| Evaluation person 5 | Airtightness | Startup time |

(2) Each evaluation person of the comprehensive performance of the battery stack is invited to use an importance value representation method of pairwise comparison as shown in Table 2 to determine an importance of the most important single-performance decision rule of the battery stack relative to other single-performance decision rules of the battery stack and an importance of the other single-performance decision rules of the battery stack relative to the least important single-performance decision rule of the battery stack, and respectively establish a vector a_{Bj}=[a_{B1}, a_{B2}, . . . , a_{Bj-1}] of the importance of the most important single-performance decision rule of the battery stack relative to other single-performance decision rules of the battery stack and a vector a_{jW}=[a_{1W}, a_{2W}, . . . , a_{j-1W}] of the importance of the other single-performance decision rules of the battery stack relative to the least important single-performance decision rule of the battery stack.

The importance of the most important single-performance decision rule of the battery stack relative to other single-performance decision rules of the battery stack and the importance of the other single-performance decision rules of the battery stack relative to the least important single-performance decision rule of the battery stack are shown in Tables 3 and 4 respectively.

TABLE 2
Importance value representation of paired
comparison of pairwise decision rules
Importance value representation

| | | | | | | | | |
|---|---|---|---|---|---|---|---|---|
| 1 | 2 | 3 | 4 | 5 | 6 | 7 | 8 | 9 |

TABLE 3
the importance of the most important single-performance decision rule of the
battery stack relative to other single-performance decision rules of the battery stack

| | | | | | Cold | | | |
|---|---|---|---|---|---|---|---|---|
| | | Open- | | Long-term | and hot | | Fuel | |
| | | circuit | | cycle | cycle | Generation | utilization | Startup |
| | Airtightness | voltage | Power | durability | durability | efficiency | rate | time |
| Evaluation | 3 | 2 | 1 | 4 | 4 | 5 | 7 | 9 |
| person 1 | | | | | | | | |
| Evaluation | 2 | 4 | 1 | 5 | 6 | 7 | 7 | 8 |
| person 2 | | | | | | | | |
| Evaluation | 2 | 1 | 2 | 3 | 3 | 4 | 5 | 7 |
| person 3 | | | | | | | | |
| Evaluation | 1 | 2 | 2 | 4 | 3 | 4 | 5 | 7 |
| person 4 | | | | | | | | |
| Evaluation | 1 | 3 | 2 | 5 | 4 | 5 | 6 | 8 |
| person 5 | | | | | | | | |

TABLE 4
The importance of other single-performance
decision rules of the battery stack relative to the least
important single-performance decision rule of the battery stack

| | Evaluation | Evaluation | Evaluation | Evaluation | Evaluation |
|---|---|---|---|---|---|
| | person 1 | person 2 | person 3 | person 4 | person 5 |
| Airtightness | 6 | 7 | 7 | 7 | 9 |
| Open-circuit | 7 | 5 | 8 | 6 | 7 |
| voltage | | | | | |
| Power | 8 | 8 | 7 | 6 | 8 |
| Long-term | 5 | 4 | 6 | 5 | 4 |
| cycle | | | | | |
| durability | | | | | |
| Cold and hot | 5 | 3 | 6 | 4 | 5 |
| cycle | | | | | |
| durability | | | | | |
| Generation | 4 | 2 | 5 | 5 | 4 |
| efficiency | | | | | |
| Fuel | 2 | 2 | 3 | 3 | 2 |
| utilization | | | | | |
| rate | | | | | |
| Startup time | 1 | 1 | 1 | 1 | 1 |

(3) Based on the following linear optimization formula, the weight W^{k}ⱼ (j=1, 2, 3, . . . , 8, k=1, 2, 3, 4, 5) of the single-performance decision rule of the battery stack determined by each evaluation person of the comprehensive performance of the battery stack is obtained; the weight W^{k}ⱼ of the single-performance decision rule of the battery stack determined by each evaluation person of the comprehensive performance of the battery stack is as shown in Table 5.

Under the precondition that a target function ξ^{L} is minimum, the following constraint conditions are to be satisfied:

$$\vert {{w}^{k}}_{B} - {a}_{B j} {{w}^{k}}_{j} \vert \leq {ξ}^{L} ;$$

$$\vert {{w}^{k}}_{j} - {a}_{j w} {{w}^{k}}_{W} \vert \leq {ξ}^{L} ;$$

$${\sum }_{j = 1}^{n} {{w}^{k}}_{j} = 1 ;$$

$${{w}^{k}}_{j} \geq 0 ;$$

when j=1,2,3, . . . , n, the above constraint conditions are all to be established;

wherein w^{k}_{B} is a weight (k=1, 2, 3, 4, 5) of the most important single-performance decision rule of the battery stack determined by the k-th evaluation person of the comprehensive performance of the battery stack; w^{k}_{W} is a weight (k=1, 2, 3, 4, 5) of the least important single-performance decision rule of the battery stack determined by the k-th evaluation person of the comprehensive performance of the battery stack; w^{k}ⱼ is a weight vector (j=1, 2, 3, . . . , 8, k=1, 2, 3, 4, 5) formed by the weight of the j-th single-performance decision rule of the battery stack determined by the k-th evaluation person of the comprehensive performance of the battery stack; ξ^{L} is the target function of the linear optimization formula.

TABLE 5
the weight of the single-performance decision rule of the battery stack
determined by each evaluation person of the comprehensive performance of the battery stack
for each performance of the battery stack

| | | Open- | | Long-term | Cold and | | Fuel | |
|---|---|---|---|---|---|---|---|---|
| | | circuit | | cycle | hot cycle | Generation | utilization | Startup |
| | Airtightness | voltage | Power | durability | durability | efficiency | rate | time |
| Evaluation | 13.19% | 19.79% | 29.26% | 9.895% | 9.90% | 7.92% | 5.65% | 4.40% |
| person 1 | | | | | | | | |
| Evaluation | 22.06% | 11.03% | 32.61% | 8.82% | 7.35% | 6.30% | 6.30% | 5.52% |
| person 2 | | | | | | | | |
| Evaluation | 16.67% | 24.65% | 16.67% | 11.12% | 11.12% | 8.34% | 6.67% | 4.76% |
| person 3 | | | | | | | | |
| Evaluation | 24.46% | 17.36% | 17.36% | 8.68% | 11.57% | 8.68% | 6.94% | 4.96% |
| person 4 | | | | | | | | |
| Evaluation | 29.24% | 13.29% | 19.93% | 7.97% | 9.97% | 7.97% | 6.64% | 4.98% |
| person 5 | | | | | | | | |

2. Based on entropy theory, the preferences of five evaluation persons of the comprehensive performances of the battery stack are aggregated to obtain the importance weight of the k-th evaluation person of the comprehensive performance of the battery stack Uₖ (k=1, 2, 3, 4, 5) and the final comprehensive weight Wⱼ (j=1, 2, 3, . . . , 8) of the j-th single-performance decision rule of the battery stack.

(1) based on an optimal model aggregated relative to an entropy value in the group decision, a personal preference of each evaluation person of the comprehensive performance of the battery stack is aggregated:

$${{W}_{j}}^{d} = \frac{{\prod }_{k = 1}^{m} {( {{W}^{k}}_{j} )}^{{{U}_{k}}^{d - 1}}}{{\sum }_{j = 1}^{n} {\prod }_{k = 1}^{m} {( {{W}^{k}}_{j} )}^{{{U}_{k}}^{d - 1}}}$$

wherein W^{k}ⱼ is a weight of the k-th evaluation person of the comprehensive performance of the battery stack for the j-th single-performance decision rule of the battery stack, Wⱼ^{d} is a comprehensive weight of the j-th single performance decision rule of the battery stack calculated in the d-th iteration, Uₖ^{d-1} is an importance weight (j=1, 2, 3, . . . , 8, k=1, 2, 3, 4, 5) of the k-th evaluation person of the comprehensive performance of the battery stack calculated in the (d−1)-th iteration.

(2) a formula Uₖ^{d}=αrₖ^{d-1}+βeₖ^{d-1} (k=1, 2, 3, 4, 5, d=0, 1, 2, 3, . . . , h) of the importance weight of the k-th evaluation person of the comprehensive performance of the battery stack calculated in the d-th iteration is established;

wherein,

$${{r}_{k}}^{d - 1} = \frac{1}{{\sum }_{j = 1}^{n} {( {{W}_{j}}^{d - 1} - {{W}^{k}}_{j} )}^{2} {\sum }_{k = 1}^{m} \frac{1}{{\sum }_{j = 1}^{n} {( {{W}_{j}}^{d - 1} - {{W}^{k}}_{j} )}^{2}}}$$

$${{e}_{k}}^{d - 1} = \frac{1 + \frac{1}{{log}_{2} n} ( {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}{m + {\sum }_{k = 1}^{m} ( \frac{1}{{log}_{2} n} {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}$$

wherein rₖ^{d-1} is a deviation weight obtained based on a total deviation amount of the comprehensive weight of the k-th evaluation person of the comprehensive performance of the battery stack calculated in the (d−1)-th iteration, eₖ^{d-1} is an entropy weight of the k-th evaluation person of the comprehensive performance of the battery stack in the (d−1)-th iteration, Uₖ^{d} is an importance weight of the k-th evaluation person of the comprehensive performance of the battery stack in the d-th iteration, W^{k}ⱼ is a weight of the k-th evaluation person of the comprehensive performance of the battery stack for the j-th single-performance decision rule of the battery stack, Wⱼ^{d-1} is a comprehensive weight of the j-th single-performance decision rule of the battery stack calculated in the (d−1)-th iteration, wherein [symbol] j=1,2,3, . . . , n, k=1,2,3, . . . , m, d is a number of iterations, d=1,2,3, . . . , h, h is determined by a specific number of iterations. α and β are 0.6 and 0.4 respectively in this example.

(3) The weight of the single-performance decision rule of the battery stack determined by five evaluation persons of the comprehensive performance of the battery stack (as shown in Table 5) and the initial importance weight Uₖ⁰=0.2 (k=1, 2, 3, 4, 5) of five evaluation persons of the comprehensive performance of the battery stack are input. Based on the aggregation algorithm of personal preferences of multiple evaluation persons of the comprehensive performance of the battery stack and the formulas (1) and (2), iteration is performed until the iteration stop condition

$$\sqrt{{\sum }_{j = 1}^{n} {( ( {{W}_{j}}^{d - 1} ) - ( {{W}_{j}}^{d} ) )}^{2}} < ε$$

(ε=0.001 in this example) is satisfied, and then iteration is stopped;

wherein Wⱼ^{d} is the comprehensive weight of the j-th single-performance decision rule of the battery stack in the d-th iteration, and Wⱼ^{d-1} is the comprehensive weight of the j-th single-performance decision rule of the battery stack in the (d−1)-th iteration.

The importance weight Uₖ (k=1, 2, 3, 4, 5) of the k-th evaluation person of the comprehensive performance of the battery stack at the time of iteration stop and the final comprehensive weight Wⱼ (j=1, 2, 3, . . . , 8) of the j-th single-performance decision rule of the battery stack are output as shown in Tables 6 and 7.

TABLE 6
the importance weight of each evaluation person of the
comprehensive performance of the battery stack

| | Evaluation | Evaluation | Evaluation | Evaluation | Evaluation |
|---|---|---|---|---|---|
| | person 1 | person 2 | person 3 | person 4 | person 5 |
| Importance | 11.62% | 11.14% | 13.59% | 45.95% | 17.70% |
| weight | | | | | |

TABLE 7
The final comprehensive weight of the single-performance decision rule
of the battery stack

| | | Open- | | Long-term | Cold and | | Fuel | |
|---|---|---|---|---|---|---|---|---|
| | | circuit | | cycle | hot cycle | Generation | utilization | Startup |
| | Airtightness | voltage | Power | durability | durability | efficiency | rate | time |
| Final | 22.42% | 17.09% | 20.62% | 9.18% | 10.65% | 8.27% | 6.74% | 5.02% |
| comprehensive | | | | | | | | |
| weight | | | | | | | | |

OF course, the above descriptions are not meant to limit the present disclosure and the present disclosure is also limited to the above embodiments. Various changes, variations, additions, or substitutions made by those skilled in the arts within the substantial scope of the present disclosure shall fall within the scope of protection of the present disclosure.

1-4. (canceled)

5. A multi-rule decision method of evaluating comprehensive performance of a battery stack, applied to evaluation on performance of a Solid Oxide Fuel Cell (SOFC) battery stack and comprising:
at step S1, selecting multiple indexes from indexes affecting the performance of the battery stack, comprising but not limited to airtightness, open-circuit voltage, power, long-term cycle durability, cold and hot cycle durability, generation efficiency, fuel utilization rate, startup time, internal reforming efficiency, and stable running current, as a single-performance decision rule of the battery stack for evaluating the comprehensive performance of the battery stack to form a decision rule vector Cⱼ=[c₁, c₂, . . . , cₙ] of the comprehensive performance of the battery stack;
at step S2, based on classical Best Worst Method (BWM) method, obtaining a weight W^{k}ⱼ of each of M evaluation persons of the comprehensive performance of the battery stack for the single-performance decision rule of the battery stack in the decision rule vector Cⱼ=[c₁, c₂, . . . , cₙ] of the comprehensive performance of the battery stack, wherein j=1,2,3, . . . , n, k=1,2,3, . . . , m, j represents the j-th single-performance decision rule of the battery stack, and k represents the k-th evaluation person of the comprehensive performance of the battery stack; and
at step S3, based on entropy theory, aggregating a weight of the single-performance decision rule of the battery stack obtained by each of the m evaluation persons of the comprehensive performance of the battery stack to obtain an importance weight Uₖ of the k-th evaluation person of the comprehensive performance of the battery stack satisfying iteration stop condition and a final comprehensive weight Wⱼ of the j-th single-performance decision rule of the battery stack, determine a comprehensive performance level of the battery stack and further determine reliability and durability of a fuel cell generation system;
wherein in the step S3, a method of obtaining the importance weight Uₖ of the k-th evaluation person of the comprehensive performance of the battery stack and the final comprehensive weight Wⱼ of the j-th single-performance decision rule of the battery stack comprises:
(i) based on an optimal model aggregated relative to an entropy value in the group decision, aggregating a personal preference of each evaluation person of the comprehensive performance of the battery stack:
$${{W}_{j}}^{d} = \frac{{\prod }_{k = 1}^{m} {( {{W}^{k}}_{j} )}^{{{U}_{k}}^{d - 1}}}{{\sum }_{j = 1}^{n} {\prod }_{k = 1}^{m} {( {{W}^{k}}_{j} )}^{{{U}_{k}}^{d - 1}}}$$
wherein W^{k}ⱼ is a weight of the k-th evaluation person of the comprehensive performance of the battery stack for the j-th single-performance decision rule of the battery stack, Wⱼ^{d} is a comprehensive weight of the j-th single-performance decision rule of the battery stack calculated in the d-th iteration, Uₖ^{d-1} is an importance weight of the k-th evaluation person of the comprehensive performance of the battery stack calculated in the (d−1)-th iteration, wherein j=1,2,3, . . . , n, k=1,2,4, . . . , m, d is a number of iterations, d=1,2,3, . . . , h, h is determined by a specific number of iterations;
(ii) establishing a formula Uₖ^{d}=αrₖ^{d-1}+βeₖ^{d-1} of the importance weight of the k-th evaluation person of the comprehensive performance of the battery stack calculated in the d-th iteration;
wherein,
$${{r}_{k}}^{d - 1} = \frac{1}{{\sum }_{j = 1}^{n} {( {{W}_{j}}^{d - 1} - {{W}^{k}}_{j} )}^{2} {\sum }_{k = 1}^{m} \frac{1}{{\sum }_{j = 1}^{n} {( {{W}_{j}}^{d - 1} - {{W}^{k}}_{j} )}^{2}}}$$
$${{e}_{k}}^{d - 1} = \frac{1 + \frac{1}{{log}_{2} n} ( {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}{m + {\sum }_{k = 1}^{m} ( \frac{1}{{log}_{2} n} {\sum }_{j = 1}^{n} ( \frac{{{W}_{j}}^{d - 1}}{{\sum }_{j = 1}^{n} {{W}^{k}}_{j}} {log}_{2} ( \frac{{{W}_{j}}^{d - 1}}{{\sum }_{j = 1}^{n} {{W}^{k}}_{j}} ) ) )}$$
wherein rₖ^{d-1} is a deviation weight obtained based on a total deviation amount of the comprehensive weight of the k-th evaluation person of the comprehensive performance of the battery stack calculated in the (d−1)-th iteration, eₖ^{d-1} is an entropy weight of the k-th evaluation person of the comprehensive performance of the battery stack in the (d−1)-th iteration, Uₖ^{d} is an importance weight of the k-th evaluation person of the comprehensive performance of the battery stack in the d-th iteration, W^{k}ⱼ is a weight of the k-th evaluation person of the comprehensive performance of the battery stack for the j-th single-performance decision rule of the battery stack, Wⱼ^{d-1} is a comprehensive weight of the j-th single-performance decision rule of the battery stack calculated in the (d−1)-th iteration, α and β are specified by the evaluation persons of the comprehensive performance of the battery stack based on actual situations, and α+β=1;
(iii) based on aggregation algorithm of personal preferences of multiple evaluation persons of the comprehensive performance of the battery stack, performing iteration, by the computer, on the formulas (i) and (ii), until
$$\sqrt{{\sum }_{j = 1}^{n} {( ( {{W}_{j}}^{d - 1} ) - ( {{W}_{j}}^{d} ) )}^{2}} < ε ,$$
and stopping the iteration;
wherein ε is determined by the evaluation of m persons of the comprehensive performance of the battery stack based on actual situations, Wⱼ^{d} is a comprehensive weight of the j-th single-performance decision rule of the battery stack calculated in the d-th iteration, and Wⱼ^{d-1} is a comprehensive weight of the j-th single-performance decision rule of the battery stack calculated in the (d−1)-th iteration; and
(iv) providing as an output of the computer, a first table identifying the importance weight Uₖ of the k-th evaluation person of the comprehensive performance of the battery stack at the time of iteration stops and a second table identifying the final comprehensive weight Wⱼ of the j-th single-performance decision rule of the battery stack, wherein Wⱼ=Wⱼ^{d}, Uₖ=Uₖ^{d};
a flow of the aggregation algorithm of the personal preferences of multiple evaluation persons of the comprehensive performance of the battery stack comprises:
P1: providing as input to the computer, the weight W^{k}ⱼ of the single-performance decision rule of the battery stack determined by each of the m evaluation persons of the comprehensive performance of the battery stack and an initial importance weight Uₖ⁰ of each of the m evaluation persons of the comprehensive performance of the battery stack;
P2: calculating a comprehensive weight value
$${{W}_{j}}^{1} = \frac{{\prod }_{k = 1}^{m} {( {{W}^{k}}_{j} )}^{{{U}_{k}}^{0}}}{{\sum }_{{j = 1}^{}}^{n} {\prod }_{k = 1}^{m} {( {{W}^{k}}_{j} )}^{{{U}_{k}}^{0}}}$$
of the single-performance decision rule of the battery stack obtained in the first iteration;
P2: calculating an importance weight of each of the m evaluation persons of the comprehensive performance of the battery stack obtained in the first iteration;
P3: based on the comprehensive weight value Wⱼ¹ of the single-performance decision rule of the battery stack and the importance weight Uₖ¹ of each of the m evaluation persons of the comprehensive performance of the battery stack obtained in the first iteration, calculating a comprehensive weight value Wⱼ² of the j-th single-performance decision rule of the battery stack in the second iteration and the importance weight Uₖ² of the k-th evaluation person of the comprehensive performance of the battery stack in the second iteration; and
P5: determining, by the computer, whether the iteration stop condition
$$\sqrt{{\sum }_{j = 1}^{n} {( ( {{W}_{j}}^{d - 1} ) - ( {{W}_{j}}^{d} ) )}^{2}} < ε \qquad ( d \geq 1 )$$
is satisfied; if the iteration stop condition is satisfied, stopping iteration by the computer and providing Wⱼ^{d}, i.e. the final comprehensive weight Wⱼ of the j-th single-performance decision rule of the battery stack as an output, and otherwise, repeating the iteration until the iteration stop condition determined by the computer is satisfied; and
determining the comprehensive performance of the battery stack based on the first table identifying the importance weight of the k-th evaluation person of the comprehensive performance of the battery stack at the time of iteration stop and based on the second table identifying the final comprehensive weight of the j-th single-performance decision rule of the battery stack.

6. The multi-rule decision method of claim 5, wherein in the step S2, a method of obtaining the weight W^{k}ⱼ of the k-th evaluation person of the comprehensive performance of the battery stack for the j-th single-performance decision rule of the battery stack comprises:
(1) selecting a most important single-performance decision rule c_{B} of the battery stack and a least important single-performance decision rule c_{W} of the battery stack from the decision rule vector Cⱼ=[c₁, c₂, . . . , cₙ] of the comprehensive performance of the battery stack;
(2) inviting each of the m evaluation persons of the comprehensive performance of the battery stack to use an importance value representation method of pairwise comparison to determine an importance of the most important single-performance decision rule of the battery stack relative to other single-performance decision rules of the battery stack and an importance of the other single-performance decision rules of the battery stack relative to the least important single-performance decision rule of the battery stack, and respectively establish a vector a_{Bj}=[a_{B1}, a_{B2}, . . . , a_{Bj-1}] of the importance of the most important single-performance decision rule of the battery stack relative to other single-performance decision rules of the battery stack and a vector a_{jW}=[a_{1W}, a_{2W}, . . . , a_{j-1W}] of the importance of the other single-performance decision rules of the battery stack relative to the least important single-performance decision rule of the battery stack;
(3) based on the following linear optimization formula, obtaining the weight W^{k}ⱼ of the single-performance decision rule of the battery stack determined by each of the m evaluation persons of the comprehensive performance of the battery stack;
wherein under the precondition that a target function ξ^{L} is minimum, the following constraint conditions are to be satisfied:
$$\vert {{w}^{k}}_{B} - {a}_{B j} {{w}^{k}}_{j} \vert \leq {ξ}^{L} ;$$
$$\vert {{w}^{k}}_{j} - {a}_{j w} {{w}^{k}}_{W} \vert \leq {ξ}^{L} ;$$
$${\sum }_{j = 1}^{n} {{w}^{k}}_{j} = 1 ;$$
$${{w}^{k}}_{j} \geq 0 ;$$
when j=1,2,3, . . . , n, the above constraint conditions are all to be established;
wherein w^{k}_{B} is a weight of the most important single-performance decision rule of the battery stack determined by the k-th evaluation person of the comprehensive performance of the battery stack;
w^{k}_{W} is a weight of the least important single-performance decision rule of the battery stack determined by the k-th evaluation person of the comprehensive performance of the battery stack;
w^{k}ⱼ is a weight vector formed by the weight of the j-th single-performance decision rule of the battery stack determined by the k-th evaluation person of the comprehensive performance of the battery stack; and
ξ^{L} is the target function of the linear optimization formula.
